(19) United States
(12) Patent Application Publication
(10) Pub. No.: US 2026/0011530 A1
(43) Pub. Date: Jan. 8, 2026

(54) Beam Plasma Source

(71) Applicants: Board of Trustees of Michigan State University, East Lansing, MI (US); Scion Plasma, LLC, East Lansing, MI (US)

(72) Inventors: Qi Hua Fan, Okemos, MI (US); David Stevenson, Dexter, MI (US); Li Qin Zhou, Okemos, MI (US)

(73) Assignees: Board of Trustees of Michigan State University, East Lansing, MI (US); Scion Plasma, LLC, East Lansing, MI (US)

(21) Appl. No.: 18/763,453

(22) Filed: Jul. 3, 2024

(51) Int. Cl. H01J 37/32; C23C 14/35; H01J 37/34

(52) U.S. Cl. CPC H01J 37/32082; C23C 14/35; H01J 37/3405; H01J 2237/081; H01J 2237/0815; H01J 2237/083; H01J 2237/332

(57) ABSTRACT

A broad beam plasma or ion source is provided, which includes an anode pole extending beyond the top surface of the cathode. A further aspect of a broad ion source includes magnets and magnetic shunts which create convex magnetic flux across and above the anode pole, which intercepts a significant portion of the magnetic flux. In another aspect, a broad beam ion source includes a magnetic surrounding cathode that prevents the magnetic flux from leaking out of the ion source. A further aspect provides a broad beam plasma source which is excited by combined DC and RF powers to create ions and reactive species to interact with specimen. Yet in a further aspect, a broad beam ion source operates simultaneously with another deposition source at the same internal pressure in a vacuum chamber for making high-quality thin films.

### BACKGROUND

The present application generally pertains to a plasma source and more particularly to an ion source apparatus that can generate a broad beam of ions.

Thin film processing is widely used for manufacturing semiconductor devices, displays, solar panels, tribological coatings, sensors, and micro-electro-mechanical systems. Conventional physical and chemical vapor depositions generally result in loosely packed atoms on a workpiece due to their limited kinetic energies at temperatures below a phase equilibrium point. The micro-porous structures lead to unstable material properties and poor device performance.

Ion sources are plasma generation devices that emit ion beams to interact with the atoms as they are deposited and subsequently modulate the film microstructures. Ion sources have the potential to promote thin-film quality at low temperatures. Conventional ion sources have multiple limitations.

One relevant conventional ion source is an anode layer ion source. Exemplary configurations are disclosed in U.S. Pat. No. 10,134,557 entitled “Linear Anode Layer Slit Ion Source” which was issued to Madocks on Nov. 20, 2018, and U.S. Patent Publication No. 2017/0029936 entitled “High Power Pulse Ionized Physical Vapor Deposition” which published to Chistyakov on Feb. 2, 2017, both of which are incorporated by reference herein.

Anode layer ion sources require a narrow gap of a few millimeters between the anode and cathode to create strong electric and magnetic fields to sustain a plasma. Hence, the emitted ion beams are narrow. A circular anode layer ion source produces a ring-shape ion beam and a linear anode layer ion source produces two distinct beams from the straight section. These beams result in a non-uniform treatment of a workpiece surface. Furthermore, the anode layer ion sources require a high voltage (e.g., >300 V) to sustain the plasma, which results in high ion energies that can damage the deposited films and/or undesirably roughen the film surfaces. On the other hand, the ion flux is determined by the ion source current, which is proportional to the discharge voltage and is generally low (e.g., ˜100 mA). It is nearly impossible to independently adjust these two basic ion beam parameters, ion energy and ion flux, while many applications require low ion energy and high flux.

Another traditional ion source is filament type ion source. An exemplary configuration is disclosed in U.S. Pat. No. 4,481,062 entitled “Electron Bombardment Ion Sources”, which was issued to Kaufman et al. on Nov. 6, 1984, and is incorporated by reference herein. The filament type ion sources commonly work at low pressure (for example, 10-4 Torr), which is incompatible with a typical sputtering pressure of 10-3 Torr. Furthermore, this type of ion source uses a filament to thermionically emit electrons, which is unsuitable for use with reactive gases required in many thin film processes. Moreover, many designs employ metal grids across an outlet, thereby disadvantageously being prone to contamination, and requiring frequent downtime and maintenance.

An inventor of this disclosure has recently patented a single beam ion source, which overcomes the limitations of the above-discussed conventional ion sources. The single beam ion source is disclosed in U.S. Pat. No. 11,049,697 entitled “Single Beam Plasma Source”, which was issued to Fan et al. on Jun. 29, 2021, and is incorporated by reference herein. The single beam ion source emits a single narrow ion beam of ˜10 mm diameter or a narrow linear ion beam of ˜10 mm width and desired length at the source emission exits. The single narrow beam is attractive for applications that require a focused ion beam on the targeted area of the workpiece. Many applications such as large-area glass coatings, display manufacturing, and solar photovoltaic module fabrication require ion-surface interactions over a wide region to achieve desired production efficiency.

In accordance with the present disclosure, a broad beam plasma or ion source is provided, which can emit a single round ion beam of ˜100 mm diameter or a linear ion beam of ˜100 mm width and any desired length. A further aspect of this ion source includes magnets and magnetic shunts which create a convex magnetic flux above the anode that extends into and intercepts a substantial portion of the convex magnetic flux. Another aspect of the ion source includes a set of magnetic shields that effectively prevent the magnetic field from leaking out of the ion source to induce a secondary plasma region on the surrounding sides of the ion source. Yet a further aspect introduces a radio frequency (RF) power superimposed (i.e., combined) on a direct current (DC) power to excite the ion source, enabling independent control of the ion current and ion energy over a wide range. An additional aspect provides a broad beam ion source operating simultaneously with other thin film deposition sources (such as sputtering magnetrons and evaporation sources) in the same process gas environment. Another aspect uses a broad beam ion source for direct thin film deposition by introducing a precursor gas that is subsequently dissociated by the ion source plasma.

The present plasma source is advantageous over conventional devices. For example, the present apparatus and method thereof advantageously emits a single broad ion beam, the cross-sectional diameter or width of which can be about 100 mm, and it can be made to the desired length in a linear configuration. Moreover, the present ion source can operate over a wide range of DC voltages (e.g., from 5 to 250 V) that lead to tunable (i.e., adjustable) ion energies for optimal ion-surface interactions. As the ion current is decoupled from the ion energy according to the present disclosure, the ion flux and ion energy can be independently controlled by RF power and DC voltage. Furthermore, the plasma beam of the present apparatus can be generated in a wide range of operating pressures (for example 0.1 mTorr to 10 Torr), which allows this source to operate with magnetron sputtering, chemical vapor deposition, plasma-enhanced chemical vapor deposition, and sublimation type evaporation processes. The present apparatus beneficially operates with many different gases including inert and reactive gases since it does not use a filament or requires a continuous flow of gas through the source. Another advantage is the broad beam ion source leads to a significant decrease in the discharge voltage and a proportional increase in the discharge current of a simultaneously operating sputtering source. This results in higher deposition rates and subsequently improved film quality.

According to an embodiment of the present disclosure, provided is an ion source including an anode pole disposed between a center cathode and a surrounding cathode, with the anode pole having a surface extending above the center cathode surface and the surrounding cathode, and a set of magnets and shunts that create convex magnetic flux lines across and above the surface of the anode pole, where the surrounding cathode further comprises an upper surrounding cathode and a lower supporting cathode, where the upper surrounding cathode includes an inner portion disposed adjacent to and beneath the anode pole surface extending above the center cathode surface and an outer portion disposed outboard of the inner portion and mounted to the lower supporting cathode, and where the lower supporting cathode is further mounted to a cathode housing.

According to an embodiment of the present disclosure, the ion source further includes a center cathode and an upper surrounding cathode that are non-magnetic materials and the lower supporting cathode is magnetic steel.

According to an embodiment of the present disclosure, the ion source includes an anode that is powered with combined direct current (DC) and radio frequency (RF) power supplies to generate a beam of ions.

According to an embodiment of the present disclosure, the RF power supply has an RF frequency is in the range from 0.1 to 27 MHz.

According to an embodiment of the present disclosure, the DC power supply has a DC voltage that is adjustable from 0 to 300 V.

According to an embodiment of the present disclosure, the ion source includes a beam of ions that is emitted from a face of the anode with ions being substantially uniformly distributed around an ion emission axis when viewed in cross-section.

According to an embodiment of the present disclosure, the ion source includes at least one of an anode pole, a set of magnets and shunts, a surrounding cathode, and a cathode housing that are circular or linearly elongated in a direction substantially perpendicular to an ion emission axis, to produce a linearly broad beam of ions.

According to an embodiment of the present disclosure, a method of generating the ion source includes controlling the ion energy of an ion source using a combination of DC and RF power supplies and controlling, using the combination of DC and RF power supplies, the ion flux density of the ion source.

According to an embodiment of the present disclosure, the method further includes disposing a pole of an anode between a center cathode and a surrounding cathode, where the anode pole surface extends above a surface of the center cathode and an adjacent surface of the surrounding cathode, and disposing a set of magnets and shunts relative to the anode and cathodes to generate convex magnetic flux lines across and above the surface of the anode pole.

According to an embodiment of the present disclosure, the method further includes constructing the center cathode of a non-magnetic material, constructing a top part of the surrounding cathode of a non-magnetic material, and constructing a lower part of the surrounding cathode of a magnetic steel.

According to an embodiment of the present disclosure, the method further includes controlling the ion energy output by adjusting the DC voltage from 0 to 300 V and controlling the ion flux density by adjusting the RF power frequency from 0.1 To 27 MHz.

According to an embodiment of the present disclosure, a process for generating a beam of ions includes establishing a background pressure in the vacuum chamber in a range of 0.0001 to 10 Torr using a vacuum pump and introducing at least one processing gas into a vacuum chamber using a mass flow controller; applying combined DC and RF power from at least one power supply to an ion source disposed within the vacuum chamber with the DC voltage adjustable from 0 to 300 V and an RF frequency in the range of 0.1 to 27 MHz to generate an ion beam; orienting the ion beam generated by the ion source toward a specimen disposed in the vacuum chamber.

According to an embodiment of the present disclosure, the process further includes configuring an anode pole located between a center cathode and a surrounding cathode with the anode pole surface extending above the center cathode surface and the inner part of the surrounding cathode surface and configuring a set of magnets and shunts creating convex magnetic flux lines across and above the surface of the anode pole.

According to an embodiment of the present disclosure, the process further includes constructing the center cathode and the top part of the surrounding cathode of non-magnetic materials and constructing the lower part of the surrounding cathode of magnetic steel.

According to an embodiment of the present disclosure, the process further includes flowing part of the processing gas through the ion source at an adjustable flow rate starting from a 0 SCCM flow rate up to a predetermined process gas pressure flow rate, where introducing the processing gas into the vacuum chamber beginning at the 0 SCCM flow rate is via an additional process gas port.

According to an embodiment of the present disclosure, the process further includes decomposing, by the ion source, a process gas into its constituent species and depositing, at least one of the species onto the specimen, forming a solid thin film on the specimen.

According to an embodiment of the present disclosure, an apparatus for depositing thin films on a specimen in a vacuum chamber using an ion source includes an ion source oriented at a first angle relative to the specimen and a physical vapor deposition source oriented at second angle relative to the specimen.

According to an embodiment of the present disclosure, the apparatus further includes an anode having a pole disposed between a center cathode and a surrounding cathode with the anode pole having a pole surface extending above the center cathode surface and a portion of the surrounding cathode, the surrounding cathode having an upper surrounding part and a lower supporting part, where the anode pole extends above an inner portion of the upper surrounding part of the surrounding cathode, and a set of magnets and shunts to generate convex magnetic flux lines across and above the anode pole surface.

According to an embodiment of the present disclosure, the ion source further includes a center cathode and an upper surrounding part of the surrounding cathode that are constructed of non-magnetic materials and the lower supporting part of the surrounding cathode is constructed of magnetic steel.

According to an embodiment of the present disclosure, the ion source further includes a combined direct current (DC and radio frequency (RF) power supplies to power the anode.

According to an embodiment of the present disclosure, the RF power supply includes an RF frequency in the range of 0.1 to 27 MHz.

According to an embodiment of the present disclosure, the DC power supply includes a DC voltage is in the range of 0 to 300 V.

According to an embodiment of the present disclosure, the apparatus includes a physical vapor deposition source that is a sputtering magnetron.

According to an embodiment of the present disclosure, the apparatus includes a physical vapor deposition source is an evaporation source.

Additional features and benefits will become apparent from the following description and appended claims taken in conjunction with the accompanying drawings.

### BRIEF DESCRIPTION OF THE DRAWINGS

FIG. 1 is a cross-sectional view showing an embodiment of the present ion source according to the present disclosure;

FIG. 2 is a cross-sectional view showing an embodiment of the present ion source according to the present disclosure, where the magnetic flux has a convex shape over the anode, which extends into and intercepts a substantial portion of the convex-shaped flux;

FIG. 3 is a partial cross-sectional view of an embodiment of the present disclosure, where the magnets and magnetic shunts create convex magnetic flux lines over the anode and prevent the flux from leaking out of the source near the outer surrounding wall;

FIG. 4 is a perspective view showing an alternate embodiment of the present ion source according to the present disclosure;

FIG. 5 is a cross-sectional view showing an embodiment of the present ion source according to the present disclosure powered by combined DC and RF power supplied;

FIGS. 6a and 6b show according to an embodiment of the present disclosure, a schematic of the present ion source and an image of the present ion source under discharge, respectively;

FIG. 7 is a graphical illustration of the measured ion energy distribution of the present ion source according to an embodiment of the present disclosure, showing that the ion energy can be controlled by the DC voltage over a wide range;

FIG. 8 graphically illustrates the discharge current-voltage relationship of the present ion source according to an embodiment of the present disclosure, indicating that the ion current can be controlled by the RF power under a given DC voltage;

FIG. 9 graphically illustrates the ion energy dependence on the excitation DC voltage and RF power of the present ion source according to an embodiment of the present disclosure, indicating that the ion energy is only controlled by the DC voltage and the RF power has little effect on the ion energy;

FIG. 10 graphically illustrates the ion energy of the present ion source according to an embodiment of the present disclosure during discharges under different pressures, indicating that the ion source can operate over a wide pressure range, which has little effect on the ion energy;

FIG. 11 is a graphical illustration of the Raman spectra of diamond-like carbon films produced by the present ion source according to an embodiment of the present disclosure, showing that the film microstructures can be modulated by the ion energy;

FIG. 12 is a diagrammatic view showing the present plasma or ion source according to an embodiment of the present disclosure in simultaneous operation with another deposition source inside a vacuum chamber;

FIG. 13 is a graphical illustration of the discharge voltage and current of a sputtering magnetron, which vary with the DC voltage applied to the broad beam ion source according to an embodiment of the present disclosure that operates simultaneously with the sputtering magnetron;

FIG. 14 is a graphical illustration of the resistivity of ZnTe thin films produced by magnetron sputtering with the assistance of the present ion source according to an embodiment of the present disclosure operating at different discharge voltages or ion energies; and

FIG. 15 shows the X-ray diffraction patterns of aluminum nitride thin films deposited with and without the ion beam treatment, indicating the present ion source according to an embodiment of the present disclosure enhances thin film crystallization at low temperatures.

### DETAILED DESCRIPTION

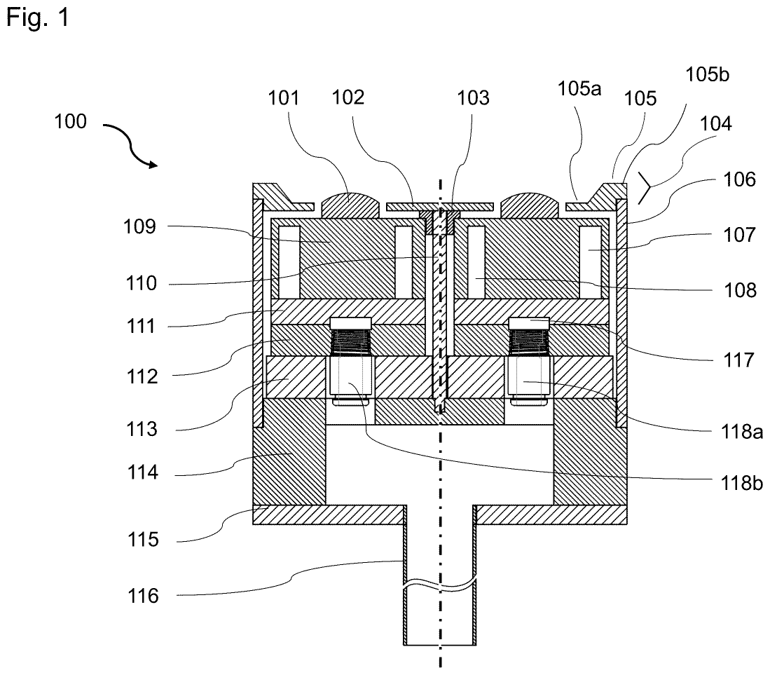

A preferred embodiment of a broad beam plasma or ion source 100 can be observed in FIG. 1, showing its cross-sectional view. Ion source 100 includes anode pole 101 mounted on anode body 109, center cathode 102 mounted on center support 110, and surrounding cathode 104 which consists of upper surrounding cathode 105 mounted on lower surrounding cathode 106 mounted on cathode housing 114. Upper surrounding cathode 105 further includes an inner portion 105a and an outer portion 105b. Outer magnet 107 and inner magnet 108 are housed in the anode body 109 and set on magnetic shunt 111. Two water connectors 118a and 118b are installed on cooling plate 112. A cooling channel 117 is formed between the magnetic shunt 111 and cooling plate 112. Insulator plate 113 electrically separates cooling plate 112 and cathode housing 114. Bottom plate 115 is mounted to the cathode housing 114 and sealed with vacuum feedthrough 116. Center insulator 103 helps to locate the center cathode 102 and is optional. It is worth noting that all the above-described components are made of conductive materials (e.g., metals and graphite) except insulator plate 113 and center insulator 103. In addition, appropriate fasteners and O-rings are needed to assemble the components and achieve vacuum sealing. All these requirements are obvious for persons with the basic skills and knowledge of vacuum technologies.

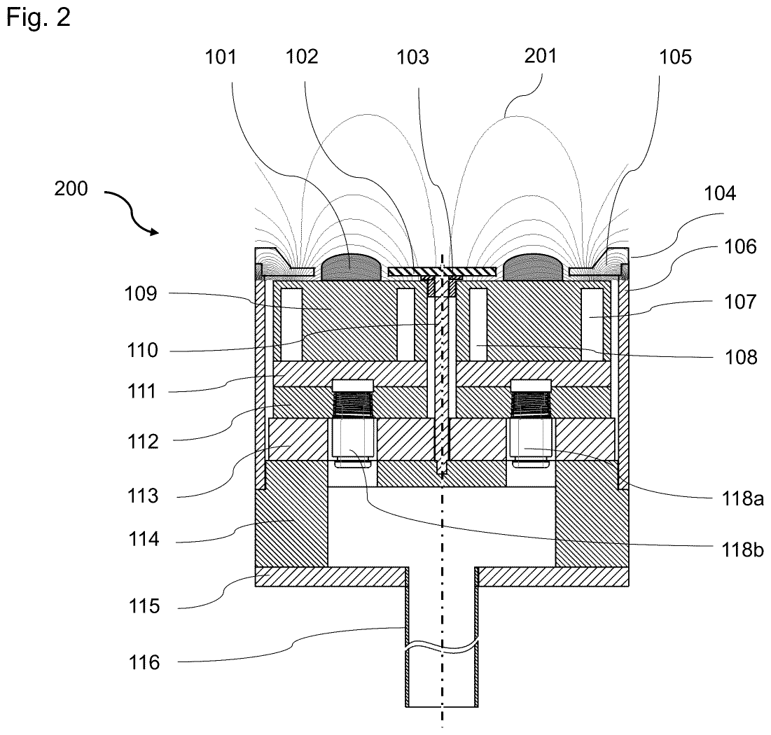

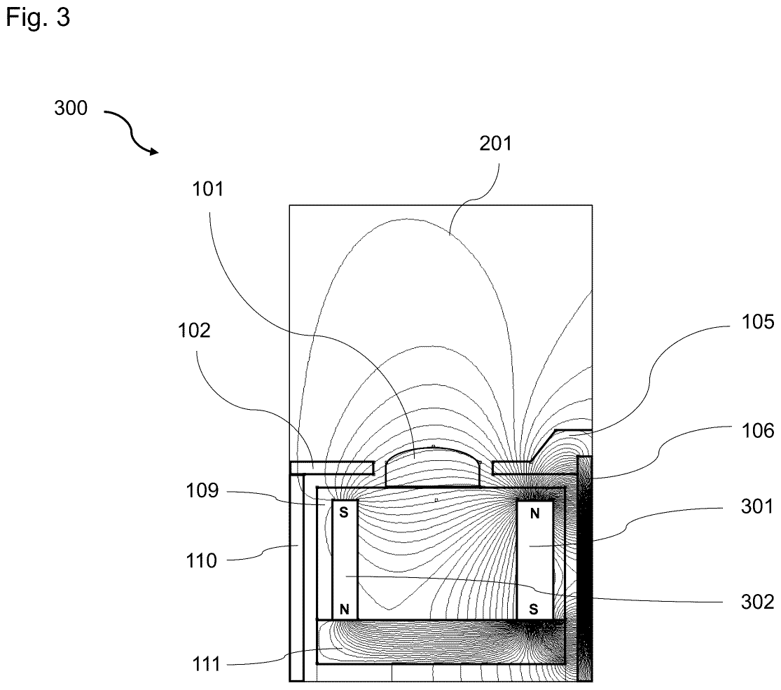

The broad beam ion source 100 possesses several critical features. First, anode pole 101 extends beyond the top surface of the center cathode 102 (e.g., by a convex shape, though other shapes are contemplated). Second, magnets 107 and 108 function together with the magnetic shunt 111 and the low surrounding cathode 106 to generate a convex magnetic flux 201 across and above the anode pole 101, as illustrated in an exemplary embodiment 200 in FIG. 2, where the anode pole 101 intercepts a portion of the magnetic flux 201. Third, the lower surrounding cathode 106 is made of magnetic steel, which can prevent the magnetic flux from leaking out of the ion source's surrounding wall, as illustrated in FIG. 3.

There are many configurations of magnets and shunts to create a convex magnetic flux 201. FIG. 3 is an exemplary embodiment of a circular broad beam plasma or ion source 300, which employs ring-shaped outer magnet 301 and inner magnet 302 together with a magnetic shunt 111 and magnetic lower surrounding cathode 106 to generate a convex magnetic flux around the anode pole 101 as well as shunt the magnetic flux from leaking out of the surrounding wall. The magnetic poles of magnets 301 and 302 are set in the opposite directions.

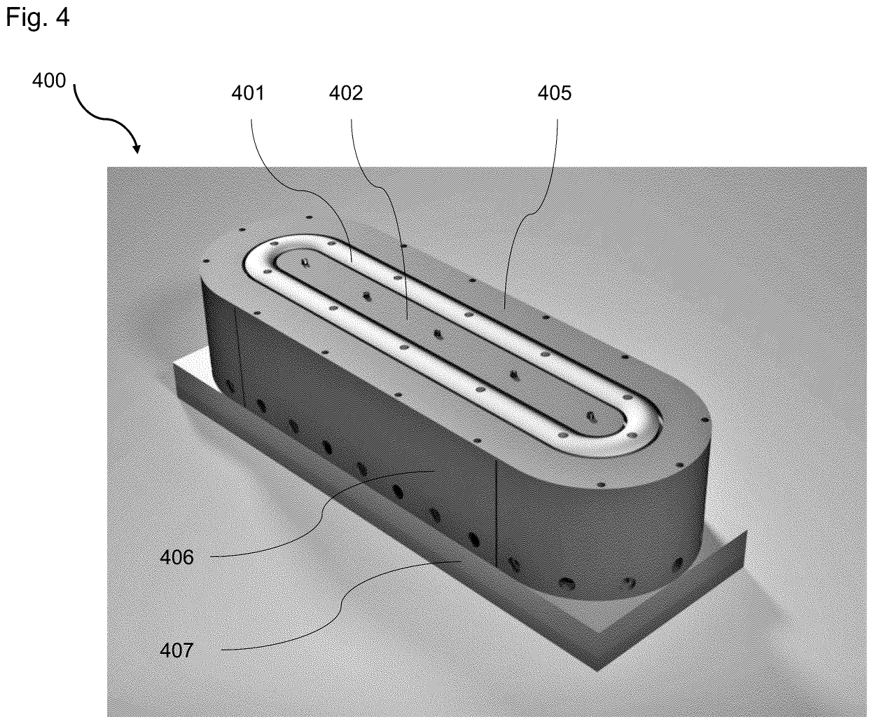

It is alternately envisioned that other arcuate shapes such as ovals, squares, or elongated shapes may be employed for the above-noted components. An alternate embodiment can be observed in FIG. 4, which illustrates a linear broad beam plasma or ion source 400 that is linearly elongated (i.e., a circular shape on each end of a linear section to form a “racetrack” shape) in a lateral direction-both the end and straight sections of the linear ion source 400 have similar cross-sectional configurations as that shown in FIGS. 1-3. For example, a linear ion source 400 includes racetrack shaped anode pole 401, center cathode 402, upper surrounding cathode 405, lower surrounding cathode 406, and bottom plate 407. Although many other components such as magnets, shunt plate, insulator plate, etc. are not shown explicitly in FIG. 4, they should be obvious for persons with the basic skills and knowledge of vacuum technologies.

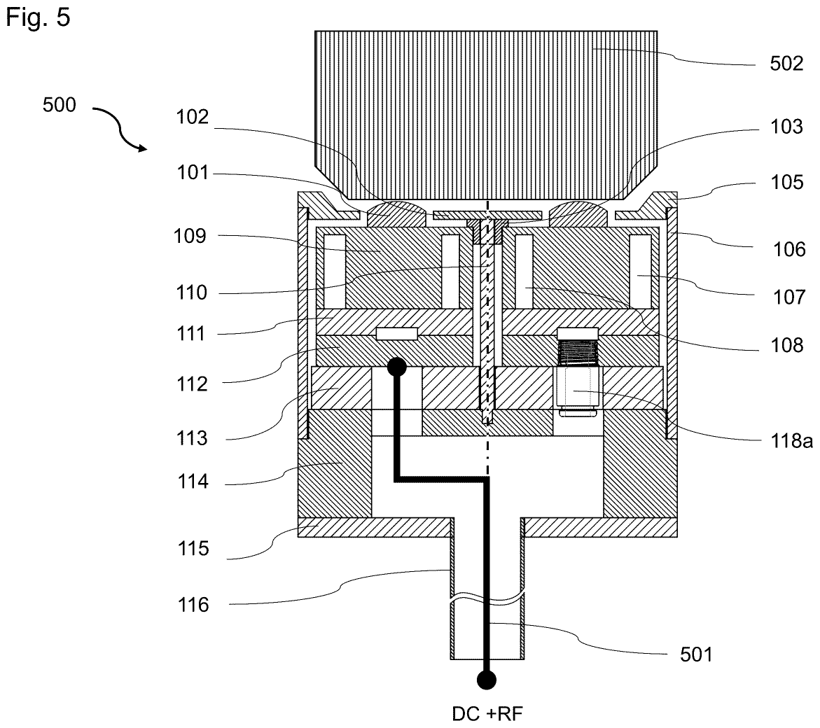

Returning to the exemplary embodiment illustrated in FIG. 5. Ion source 500 is powered by DC, RF, or DC+RF power supplies through cable 501, which is connected to the cooling plate 112. The RF frequencies are preferably in the range of about 1 MHz to 27 MHz, and more preferably 13.56 MHz. The DC voltage can start from 5 V up to 1,000 V, and more preferably <300 V. Anode pole 101, anode body 109, magnetic shunt 111, and cooling plate 112 are electrically conductive and, therefore, they are at the same electric potential. When a DC power supply is used, a positive potential relative to the ground potential is provided to the ion source. On the other hand, center cathode 102 and center support 110, upper surrounding cathode 105 and lower surrounding cathode 106, cathode housing 114, bottom plate 115, and vacuum feedthrough 116 are all connected to ground potential in common applications. When ion source 500 is powered by DC, RF, or DC+RF, it emits a broad ion beam 502.

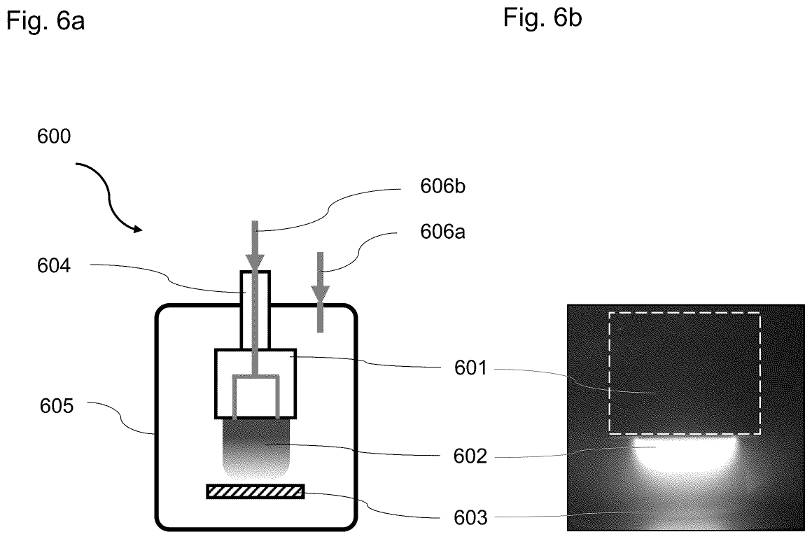

In one embodiment shown in FIGS. 6a-6b, ion source apparatus 600 includes a broad beam ion source 601 installed in a vacuum chamber 605 using a vacuum feedthrough 604. Before the ion source is energized, at least one processing gas is introduced in the vacuum chamber 605 from 0 SCCM (standard cubic centimeters per minute) to establish a working pressure (e.g., a predetermined pressure). The processing gas can be controlled by a mass flow controller 606a to flow directly into the vacuum chamber 605. Alternatively, the process gas can be controlled by a mass flow controller 606b (e.g., a different port) to flow through the ion source 601 into the chamber. Then a DC, RF, or combined DC+RF power is supplied to the ion source, creating plasma or ion beam 602, which could ionize, excite, and dissociate the precursor gas. Depending on the precursor gas used, thin films may form on substrate 603, which is known as plasma-enhanced chemical vapor deposition. A distinct feature of the broad beam plasma source operation is it simultaneously delivers a beam of ions with controllable flux and energy to interact with the deposited film, enabling effective modulation of the film microstructures at temperatures far below the phase equilibrium condition. In some cases, the plasma created by the ion source in a reactive gas environment can remove the deposited film or clean the substrate surface, enabling surface etching or cleaning

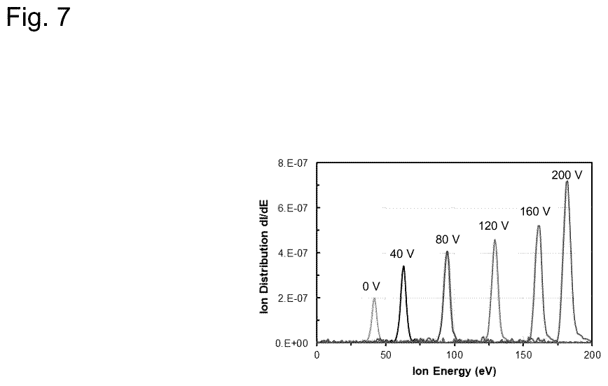

The broad beam ion sources illustrated in FIGS. 1-6 enable widely tunable ion energy that can be controlled by the applied DC voltage. FIG. 7 illustrates the ion energy distribution as the DC voltage changes from 0 to 200 V. It is clear that the broad beam ion source can deliver ions with a narrow distribution of ion energy, which is proportional to the DC voltage. This feature advantageously allows optimum ion-surface interactions for specific materials.

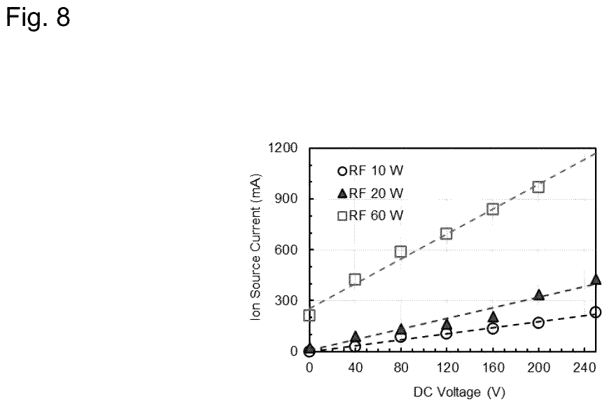

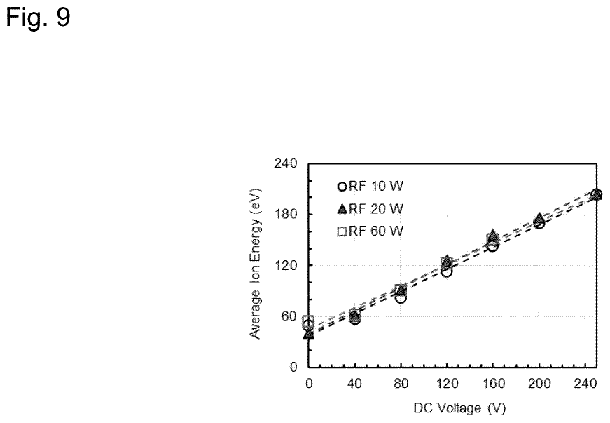

In addition to ion energy, ion flux is also a critical parameter that affects the ion-surface interactions. Conventional ion sources nearly cannot independently control these two parameters, which are strongly coupled. The broad beam ion source illustrated in FIGS. 1-6 enables widely tunable ion flux or ion current at a given DC voltage by applying an RF power superimposed on a DC voltage. An example is illustrated in FIG. 8, showing an 8-10 times increase in the ion current as the RF power changes from 10 to 60 W under a given DC voltage. It is worth noting that 60 W is a small RF power; even the smallest commercial lab-scale RF power supply can deliver 300 W RF power. Hence, the ion current can be more significantly increased by using a higher RF power. On the other hand, the RF power has almost no effect on the ion energy, as illustrated in FIG. 9, which shows that the ion energy is mainly controlled by the DC voltage. Therefore, the broad beam plasma source allows independent control of the ion energy and ion flux over a wide range, especially in the range of low energy and high flux. It is worth noting that the broad beam plasma source advantageously generates high ion current using combined DC and RF powers as compared to conventional anode layer ion sources.

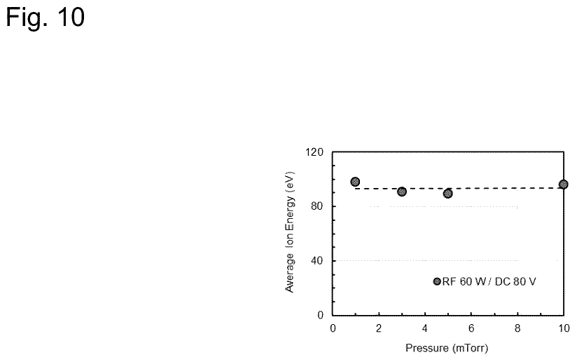

The broad beam ion sources illustrated in FIGS. 1-6 can operate over a wide range of gas pressure. This is critical to ensure the broad beam ion sources are compatible with different processes such as chemical vapor deposition, sputtering, surface cleaning, and etching. FIG. 10 shows that in the common pressure range of magnetron sputtering (1-10 mTorr), the ion energy is nearly not affected by the gas pressure.

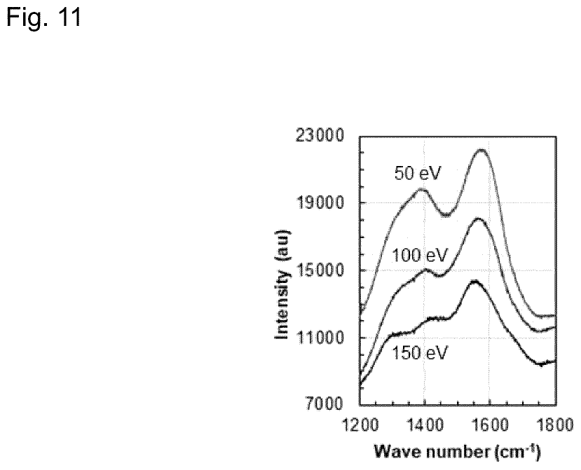

The ion source apparatus 600 shown in FIG. 6 can be used for ion beam enhanced chemical vapor deposition to fabricate various thin films using different precursor gases. One specific preferred process is to introduce a hydrocarbon gas, such as C₂H₂ into a vacuum system, in which the ion source is installed. The process gas establishes a working pressure and then the ion source is excited with DC, RF, or DC+RF powers. A carbon film is subsequently formed on the substrate. FIG. 11 shows Raman spectra of carbon films produced with the broad beam ion source at different ion energies from 50 to 150 eV. The ion energy can effectively modulate the microstructure of the carbon films as evidenced by the changes in the peak position and intensity of the G-band around 1580 cm⁻¹ and D-band around 1380 cm⁻¹. Other hydrocarbon gases, such as CH₄, can be also used to make carbon-based coatings. A variety of precursor gases can be used to deposit different thin films using a similar process as described above. Examples of the process gases include but are not limited to hexamethyldisiloxane (HMDSO) for making SiO₂ thin films, hexamethyldisilazane (HMDSN) for making Si₃N₄ thin films, mixed precursor gases (e.g., HMDSO+HMDSN) to for making SiON thin films, and so on.

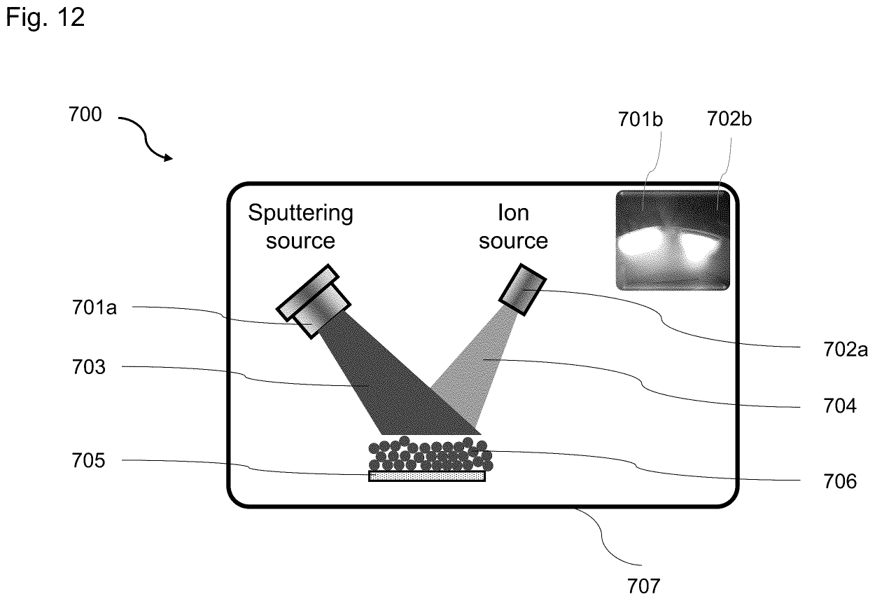

In another embodiment shown in FIG. 12, thin film deposition apparatus 700 includes a sputtering source 701a/701b and the broad beam ion source 702a/702b installed in vacuum chamber 707. These two sources operate simultaneously to grow thin films, as illustrated in the inserted image. One or more sputtering gases are introduced into vacuum chamber 707 to establish a desired processing pressure. During operation, the sputtered target material 703 is deposited onto the surface of specimen 705, forming a thin film consisting of the sputtered atoms 706. At the same time, ion beam 704 is transmitted from ion source 702a/702b to specimen 705, interacting with the sputtered atoms 706. The broad beam ion source aided magnetron sputtering is expected to directly improve the film quality such as density, electric conductivity, and barrier properties. This ion beam assisted thin-film growth is ideally suited for achieving super-smooth thin films and also for fabricating polycrystalline thin films at low temperatures such as room temperature.

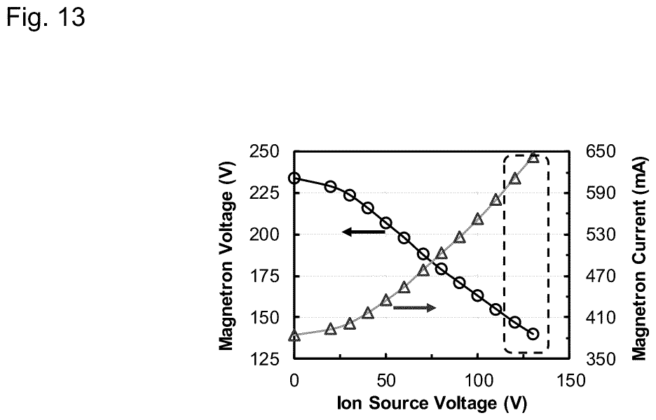

Thin film deposition apparatus 700 advantageously enable a so-called “soft sputtering mode”, as illustrated in FIG. 13. As the broad beam ion source voltage increases, the magnetron discharge current also increases. Since the power supplied to the sputtering magnetron is kept at a constant value, the magnetron discharge voltage decreases accordingly, resulting in a magnetron discharge mode that features low voltage and high current. This soft sputtering mode is advantageous over conventional magnetron sputtering in two aspects. First, it leads to higher thin film deposition rates due to the sublinear nature of sputtering yield dependence on the voltage. Second, it eliminates high energy sputtered atoms and large sputtered clusters, promoting the film quality.

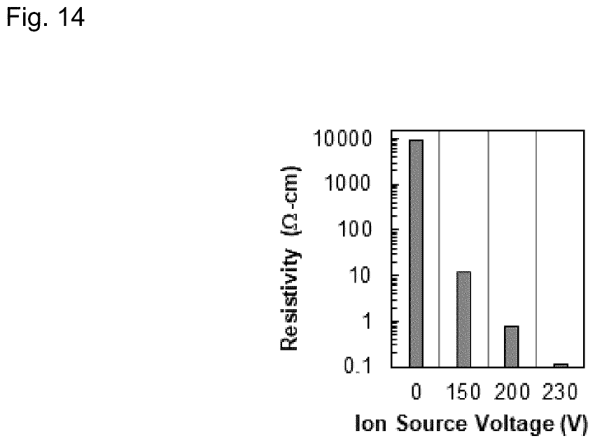

One example application of the ion source enhanced magnetron sputtering is to deposit ZnTe thin films. FIG. 14 shows the resistivity of ZnTe thin films of 100 nm thickness deposited with the broad beam ion source enhanced magnetron sputtering of a ZnTe target. As the ion energy increases, the film resistivity decreases exponentially due to the ion beam enhanced crystallization and densification of the deposited film.

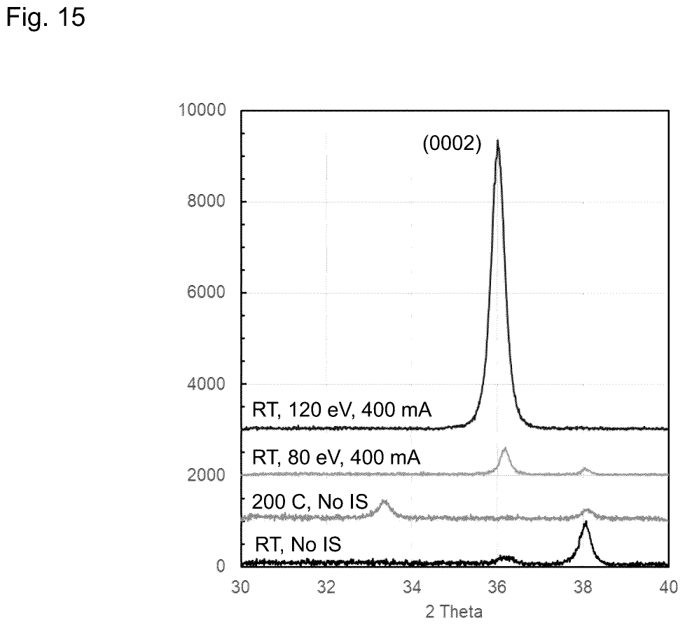

Another example of the ion source enhanced magnetron sputtering is low-temperature deposition of (0002) preferentially oriented AlN polycrystalline thin films for piezoelectric devices. This example represents reactive sputtering deposition of thin films. The sputtering target is a pure element such as aluminum or an alloy. The sputtering gas is nitrogen or a mixture of argon and nitrogen. The ion source operates simultaneously with the sputtering magnetron. FIG. 15 shows the X-ray diffraction spectra of AlN thin films deposited with and without the ion source. The results indicate several conclusions. 1) At room temperature (RT), AlN thin film deposited without the ion source (No IS) is amorphous-like with little crystallization and random orientation. 2) Even if heated up to 200° C., the AlN film is still amorphous-like with little crystallization and still random orientation. 3) At room temperature with the ion source on and an ion energy of 80 eV, (0002) crystal orientation appears. 4) At room temperature with the ion source on and an ion energy of 120 eV, the AlN film is significantly crystallized with preferential (0002) orientation. Similar processes apply to a broad variety of thin films including but not limited to oxide thin films such as indium-tin oxide, tantalum doped tin oxide, F-doped tin oxide, Niobium oxide, titanium oxide, and so on. In these cases, oxygen gas is used. The sputtering targets can be metals or oxides.

Still another example of the ion source enhanced magnetron sputtering is the deposition of ultra-thin metal thin films, such as silver. In this case, pure inert gas is used for sputtering and ion source discharges. The substrate can be optionally pretreated with the ion source. The silver films usually have a total thickness of 5-15 nm. At least the initial 3 nm thickness of the silver film is simultaneously treated with the ion source, resulting in continuous and smooth silver films.

While various embodiments have been disclosed, it should be appreciated that other variations may be employed. For example, specific magnet and shunt quantities and shapes may be varied although some of the desired benefits may not be realized. Additionally, external body, insulator and base shapes and sizes may be varied, although certain advantages may not be achieved. Furthermore, exemplary target and specimen materials have been identified but other materials may be employed. Moreover, each of the features may be interchanged and intermixed between any of the disclosed embodiments, and any of the claims may be multiply dependent on any of the others. Changes and modification are not to be regarded as a departure from the spirit or the scope of the present disclosure.

While various applications of the broad beam plasma or ion sources have been disclosed, using the sources for other applications, such as direct sputtering or etching a surface, is not to be regarded as a departure from the spirit or the scope of the present disclosure.

What is claimed is:

1. An ion source comprising:
an anode pole disposed between a center cathode and a surrounding cathode, with the anode pole having a surface extending above a center cathode surface and the surrounding cathode; and
a set of magnets and magnetic shunts that create substantially convex magnetic flux lines across and above the surface of the anode pole,
wherein the surrounding cathode further comprises an upper surrounding cathode and a lower supporting cathode,
wherein the upper surrounding cathode includes an inner portion disposed adjacent to and beneath the anode pole surface extending above the center cathode surface and an outer portion disposed outboard of the inner portion and mounted to the lower supporting cathode, and wherein the lower supporting cathode is further mounted to a cathode housing.

2. The ion source of claim 1, wherein the center cathode and the upper surrounding cathode are non-magnetic materials and the lower supporting cathode is magnetic steel.

3. The ion source of claim 1, wherein the anode is powered with combined direct current (DC) and radio frequency (RF) power supplies to generate a beam of ions.

4. The ion source of claim 3, wherein the RF frequency in the range from 0.1 to 27 MHz.

5. The ion source of claim 3, wherein the DC voltage is adjustable from 0 to 300 V.

6. The ion source of claim 3, wherein a beam of ions is emitted from a face of the anode, the ions being substantially uniformly distributed around an ion emission axis when viewed in cross-section.

7. The ion source of claim 3, wherein at least one of the anode pole, the set of magnets and magnetic shunts, the surrounding cathode, and the cathode housing are circular or linearly elongated in a direction substantially perpendicular to the ion emission axis, to produce a linearly broad beam of ions.

8. A method comprising:
controlling the ion energy of an ion source using a combination of DC and RF power supplies; and
controlling, using the combination of DC and RF power supplies, the ion flux density of the ion source.

9. The method of claim 8, further comprising:
disposing a pole of an anode between a center cathode and a surrounding cathode, wherein the anode pole surface extends above a surface of the center cathode and an adjacent surface of the surrounding cathode; and
disposing a set of magnets and shunts relative to the anode and cathodes to generate convex magnetic flux lines across and above the surface of the anode pole.

10. The method of claim 9, further comprising:
constructing the center cathode of a non-magnetic material;
constructing a top part of the surrounding cathode of a non-magnetic material; and
constructing a lower part of the surrounding cathode of a magnetic steel.

11. The method of claim 8, further comprising controlling the ion energy output by adjusting the DC voltage from 0 to 300 V and controlling the ion flux density by adjusting the RF power frequency from 0.1 To 27 MHz.

12. A process for generating a beam of ions comprising:
establishing a background pressure in the vacuum chamber in a range of 0.0001 to 10 Torr using a vacuum pump and introducing at least one processing gas into a vacuum chamber using a mass flow controller;
applying combined DC and RF power from at least one power supply to an ion source disposed within the vacuum chamber with the DC voltage adjustable from 0 to 300 V and an RF frequency in the range of 0.1 to 27 MHz to generate an ion beam;
orienting the ion beam generated by the ion source toward a specimen disposed in the vacuum chamber.

13. The process of claim 12, wherein the ion source further comprises:
configuring an anode pole located between a center cathode and a surrounding cathode with the anode pole surface extending above the center cathode surface and the inner part of the surrounding cathode surface; and
configuring a set of magnets and shunts creating convex magnetic flux lines across and above the surface of the anode pole.

14. The process of claim 13, further comprising constructing the center cathode and the top part of the surrounding cathode of non-magnetic materials and constructing the lower part of the surrounding cathode of magnetic steel.

15. The process of claim 12, further comprising flowing part of the processing gas through the ion source at an adjustable flow rate starting from a 0 SCCM flow rate up to a predetermined process gas pressure flow rate, wherein introducing the processing gas into the vacuum chamber beginning at the 0 SCCM flow rate is via an additional process gas port.

16. The process of claim 12, further comprising decomposing, by the ion source, a process gas into its constituent species and depositing, at least one of the species onto the specimen, forming a solid thin film on the specimen.

17. (canceled)

18. (canceled)

19. The ion source of claim 1, wherein the magnetic shunts are composed of a ferromagnetic material having a relative permeability greater than 100.

20. The ion source of claim 3, wherein a ratio of RF power to DC power is adjustable to fine-tune ion flux independently of ion energy.

21. The ion source of claim 6, wherein the emitted ion beam has a substantially sharp energy distribution peak with a typical full-width-at-half-maximum value of less than 25 eV.

22. The ion source of claim 1, wherein the anode pole is formed of a material selected from the group consisting of aluminum, stainless steel, titanium, molybdenum, tungsten, and graphite.

23. The ion source of claim 1, wherein the convex magnetic flux lines create a confinement zone that stabilizes plasma discharge during operation.

24. An apparatus for depositing thin films on a specimen in a vacuum chamber comprising:
a physical vapor deposition source oriented toward the specimen;
an ion source oriented toward the specimen, the ion source comprising:
an anode having a pole disposed between a center cathode and a surrounding cathode, with the anode pole having a pole surface extending above the center cathode surface and a portion of the surrounding cathode;
the surrounding cathode having an upper surrounding part and a lower supporting part, wherein the anode pole extends above an inner portion of the upper surrounding part of the surrounding cathode;
a set of magnets and magnetic shunts to generate convex magnetic flux lines across and above the anode pole surface; and
a gas flow control unit configured to direct gases either entirely into the vacuum chamber or partially through the ion source to establish a working pressure and facilitate plasma discharge.

25. The apparatus of claim 24, wherein ion source comprises a center cathode and an upper surrounding cathode that are constructed of non-magnetic materials and a lower supporting part of the surrounding cathode that is constructed of magnetic steel.

26. The apparatus of claim 24, wherein the ion source is powered by a combined direct current (DC) and radio frequency (RF) power supplies.

27. The apparatus of claim 26, wherein the ion source includes an RF power supply operating at a frequency in the range of 0.1 to 27 MHz.

29. The apparatus of claim 26, wherein the ion source includes a DC power supply providing a voltage in the range of 0 to 300 V.

30. The apparatus of claim 24, wherein the physical vapor deposition source is a sputtering magnetron.

31. The apparatus of claim 24, wherein the physical vapor deposition source is an evaporation source.
